(19) United States
(12) Patent Application Publication
(10) Pub. No.: US 2017/0084431 A1
(43) Pub. Date: Mar. 23, 2017

(54) MODULE RETENTION DURING A SPUTTER PROCESS

(71) Applicant: Apple Inc., Cupertino, CA (US)

(72) Inventor: Phillip R. SOMMER, Newark, CA (US)

(21) Appl. No.: 15/263,051

(22) Filed: Sep. 12, 2016

Related U.S. Application Data
(60) Provisional application No. 62/221,486, filed on Sep. 21, 2015.

(51) Int. Cl. H01J 37/32; C23C 14/34; H01L 21/683

(52) U.S. Cl. CPC H01J 37/32715; H01L 21/6836; C23C 14/34

(57) ABSTRACT

Methods of retaining a module for a sputter, plating, or other semiconductor manufacturing process include mounting the module to a carrier using an adhesive layer, curing the adhesive layer, sputtering a material to the module, and removing the module from the carrier such that the cured adhesive layer remains on the carrier and leaves no residue on the module. The module can be immediately ready for another surface mount process. The adhesive can be a UV-curable liquid applied to the carrier, and the cured adhesive layer can be cleaned from the carrier to prepare the carrier for reuse. Component retention systems that hold electronic components during a manufacturing process can include a carrier configured for mounting the electronic components thereto and an adhesive configured to form a UV-curable adhesive layer therebetween. The cured layer stays with the carrier upon separation, and holes in the carrier can be used to eject the processed components.

### CROSS-REFERENCE TO RELATED APPLICATION

This application claims the benefit of U.S. Provisional Patent Application No. 62/221,486, filed on Sep. 21, 2015, which is incorporated by reference herein in its entirety for all purposes.

### FIELD

The described embodiments relate generally to electronic component processing. More particularly, the described embodiments relate to retaining components during a semiconductor manufacturing process.

### BACKGROUND

Sputtering typically involves ejecting small particles of material from a source onto a substrate or other object, such as to plate or otherwise coat the object with the material during semiconductor manufacturing. Other plating processes and similar procedures are also often used in the manufacture of semiconductors and other components. Current sputter, plating, and other processes often rely on the use of an ink or a high temperature tape to hold or secure a component or object to a separate carrier or other handling component while the component or object is being sputtered, plated, or otherwise processed. Tapes and inks typically do not perform well at high temperatures over 150° C., however, such that adhesive burns, adhesive residues, and difficulties removing sputtered or plated items from the carriers post-processing are often issues. Added steps that deal with these issues are thus often a part of many such manufacturing processes. Furthermore, inks and tapes typically require interaction with a flat surface on the component or other object in order to be effective. Where the component or object surface has features or is otherwise not flat, various further considerations might be made, or effectiveness might be lessened.

While sputter, plating, and other manufacturing processes using inks and tapes have worked well in the past, there can be room for improvement. Accordingly, there is a need for improved systems and methods that secure objects during manufacturing processes in a more convenient and streamlined manner.

### SUMMARY

Representative embodiments set forth herein disclose various structures, methods, and features thereof for the disclosed component retention systems. In particular, the disclosed embodiments set forth methods for retaining or securing a component during a sputter, plating, or other manufacturing process, as well as the component retentions systems that used for such methods. These can involve the use of a curable and removable adhesive, among other items.

According to various embodiments, the disclosed component retentions systems can secure components during a manufacturing process. An exemplary component retention system can include at least: 1) a carrier configured for mounting a component thereto, and 2) an adhesive configured to form a layer that couples the carrier and component. The adhesive can be a liquid that is curable under ultraviolet (“UV”) light to form a cured adhesive layer, which can then remain on the carrier and leave no residue on the component as the component is processed and removed from the carrier. Holes in the carrier can help eject processed components.

In some embodiments, methods of retaining a module for a sputter process include mounting the module to a carrier using an adhesive layer, curing the adhesive layer, sputtering a material to the module, and removing the module from the carrier such that all of the adhesive layer is removed from the module when the module is removed from the carrier. The removed module can be immediately ready for another surface mount process. The adhesive can be a UV-curable liquid applied to the carrier that is later cleaned from the carrier to prepare the carrier for reuse. Other method steps can include applying an adhesive to a carrier, placing an electronic component onto the adhesive, curing the adhesive, performing a manufacturing process to the electronic component, and removing the electronic component from the carrier, wherein all of the adhesive is removed from the electronic component thereby.

This Summary is provided merely for purposes of summarizing some example embodiments so as to provide a basic understanding of some aspects of the subject matter described herein. Accordingly, it will be appreciated that the above-described features are merely examples and should not be construed to narrow the scope or spirit of the subject matter described herein in any way. Other features, aspects, and advantages of the subject matter described will become apparent from the following Detailed Description, Figures, and Claims.

### BRIEF DESCRIPTION OF THE DRAWINGS

The included drawings are for illustrative purposes and serve only to provide examples of possible structures and methods for the disclosed component retention systems. These drawings in no way limit any changes in form and detail that may be made to the embodiments by one skilled in the art without departing from the spirit and scope of the embodiments. The embodiments will be readily understood by the following detailed description in conjunction with the accompanying drawings, wherein like reference numerals designate like structural elements.

FIG. 1A illustrates in front perspective view an exemplary carrier for a module retention system according to various embodiments of the present disclosure.

FIG. 1B illustrates in front perspective view an alternative carrier for a module retention system according to various embodiments of the present disclosure.

FIG. 2A illustrates in top plan view an exemplary module that can be retained by a component retention system according to various embodiments of the present disclosure.

FIG. 2B illustrates in front perspective view the exemplary module of FIG. 2A according to various embodiments of the present disclosure.

FIG. 2C illustrates in front perspective view an exemplary automated adhesive to carrier application according to various embodiments of the present disclosure.

FIG. 3 illustrates in front perspective view an exemplary automated module placement application to the carrier and adhesive according to various embodiments of the present disclosure.

FIG. 4 illustrates in front perspective view an exemplary automated UV-layer curing process according to various embodiments of the present disclosure.

FIG. 5 illustrates a flowchart of an exemplary method for retaining a module during a sputter process according to various embodiments of the present disclosure.

FIG. 6 illustrates in block diagram format an exemplary computing device that can be used to implement the various components and techniques described herein according to various embodiments of the present disclosure.

### DETAILED DESCRIPTION

Securing or retaining electronic components during semiconductor manufacturing processes is commonly done by way of inking or taping the electronic components to separate carriers. Adhesive burns, adhesive residues, and difficulties removing sputtered or plated objects from carriers are often issues that result in added steps and inconveniences. Providing a component surface that is flat for mounting purposes is often a significant consideration as well. Improvements that provide for fewer process steps and less difficulties in retaining components may then be desirable. The embodiments set forth herein thus provide various structures and methods for using module retention systems that do not require inks or tapes, but that are still efficient and suitable for use in sputter, plating and other similar processes.

In various embodiments, a component retention system can include at least a carrier configured for mounting components and an adhesive that couples the carrier and components. The adhesive can be a UV-curable liquid that forms a cured adhesive layer to retain the components in place on the carrier during a sputter, plating, or other manufacturing process. The cured adhesive layer can then remain on the carrier and leave no residue on the components after the components are processed and removed from the carrier. Holes in the carrier can help eject the sputtered or otherwise processed components, which are then ready for another surface mount process without requiring any cleaning or further preparation steps to the components.

In various embodiments, methods of retaining a module for a sputter process include mounting the module to a carrier using an adhesive layer, curing the adhesive layer, sputtering a material to the module, and removing the module from the carrier such that the cured adhesive layer remains on the carrier and leaves no residue on the module. The removed module can be immediately ready for another surface mount process. The adhesive can be a UV-curable liquid applied to the carrier that is later cleaned from the carrier to prepare the carrier for reuse.

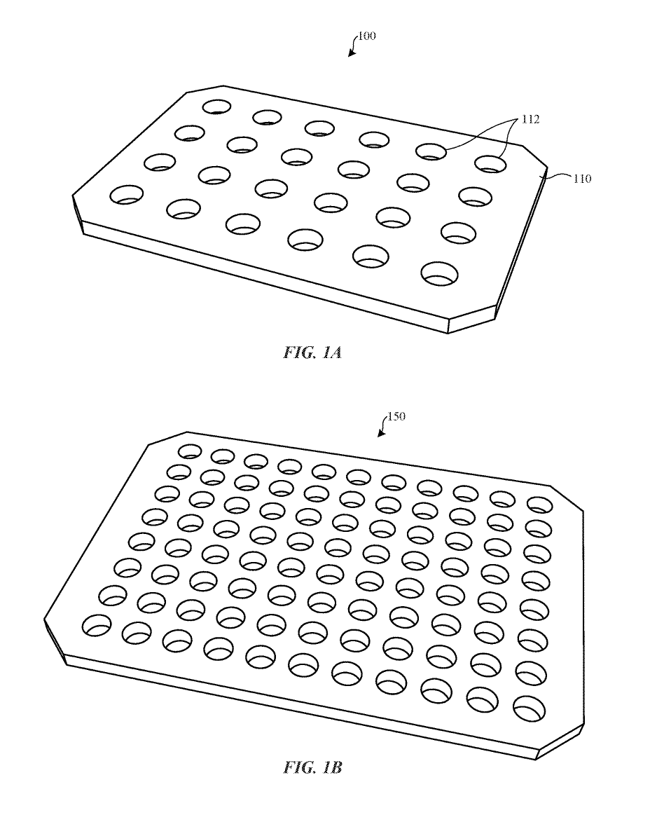

The foregoing approaches provide various structures and methods for the disclosed module retention during processing systems. A more detailed discussion of these structures, methods, and features thereof is set forth below and described in conjunction with FIGS. 1-6, which illustrate detailed diagrams of devices and components that can be used to implement these structures, methods, and features.

Turning first to FIG. 1A, an exemplary carrier for a module retention system is illustrated in front perspective view. Carrier 100 can be a generally mobile and planar piece of equipment having an upper surface 110 that is adapted for having a plurality of components (not shown) mounted thereto. Such components can be electrical or electronic components for use in an electronic device, for example. Various locations about upper surface 110 can be adapted for mounting separate components, each of which can have a hole 112 and/or other features associated therewith. As shown, carrier 100 can have 24 locations for mounting 24 separate components to be processed thereto, such as in a 6×4 array or grid. Of course, other patterns, sizes, arrangements, and numbers of locations may alternatively be used for a given carrier. Each hole 112 can function as an ejection hole that can be used to facilitate the removal of a component mounted to a given location about the hole 112. This can be accomplished by way of a pin (not shown) or other suitable component that is inserted into the hole 112 to push a processed component away from the carrier 100 after processing, for example.

Carrier 100 can be a piece of glass or other suitable UV transparent material that is configured to hold numerous components in a mass manufacturing process. Transparency to UV light can help to facilitate a UV cure of an associated adhesive, as detailed below. Carrier 100 can have a thickness of about 5 mm to about 20 mm in various embodiments, although thinner or thicknesses may be used for the carrier depending upon the relevant mounted components, applications, and processes. In some embodiments, each location having a hole 112 and/or other features for an individual mounted component can be about 20-50 mm in width and length. Each hole 112 can have a diameter of about 5 mm to about 20 mm. Again, other dimensions are also possible depending upon the relevant mounted components, applications, and processes.

FIG. 1B illustrates in front perspective view an alternative carrier for a module retention system according to various embodiments of the present disclosure. Carrier 150 can be substantially similar to carrier 100 of FIG. 1A, such that it may be formed from the same or similar UV-transparent material, and have the same or similar thickness and/or other dimensions. Rather than 24 locations, however, carrier 150 can have 88 locations for mounting 88 separate components to be processed, such as in a 8×11 grid or array. Again, any other number of mounting locations for separate components might be present in any suitable pattern on a given carrier. In some embodiments, a given carrier may have only one mounting location for a single component rather than multiple locations for multiple components.

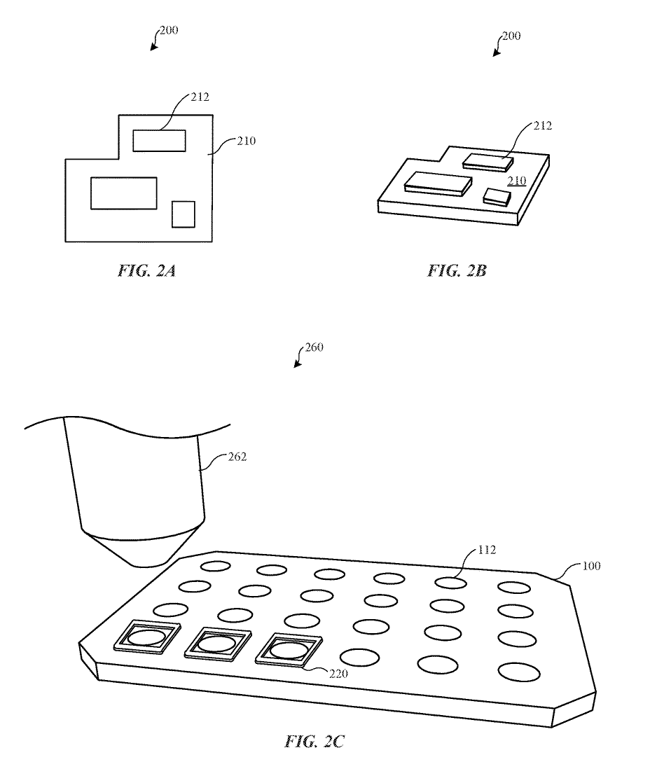

Moving next to FIGS. 2A and 2B an exemplary module that can be retained by a component retention system is illustrated in top plan and front perspective views respectively. Module 200 can be a component that is suitable for mounting to a module retention system carrier, such as carrier 100 or carrier 150 above. In various embodiments, module 200 can include an active surface 210 having one or more features 212 situated thereupon. Features 212 can include various processing, connecting, or other electrical components. Module 200 can form some or all of a system in package (“SIP”) electronic component in some embodiments. Such a SIP or module 200 can be partially formed, such as where a sputter, plating, and/or other manufacturing process has yet to be performed on the module 200. Such a manufacturing process can serve to add a coating or other element or layer to module 200. Although a sputtering process is frequently discussed herein by way of example, it will be understood that other plating and manufacturing processes may similarly apply where a given module 200 or other component is to be retained or held.

Retaining or holding the module 200 or other component being sputtered can be an issue. A common carrier or other portable item is often used for this, so that may components can be sputtered or coated at the same time. While an inking or taping process is often used to hold modules or other components to a carrier, this can result in an overall process that takes up to 20-25 steps to ink or tape the module, sputter, and then remove and clean the ink or tape from the module. Furthermore, inking or taping typically requires that flat surfaces be used on both the components and the carrier. As such, inking or taping is typically not possible or of limited effectiveness for any curved surfaces, three-dimensional surfaces, surfaces having balls or other features, and any other non-flat surfaces on a component. Since inking or taping can thus be a limiting, time consuming, and costly process, alternative ways of retaining modules to carriers may be preferable.

One alternative way of retaining a module 200 to a carrier 100 can involve the use of a curable or hardening adhesive, such as a liquid UV-curable adhesive. Such an adhesive can be placed between a given module 200 and a given carrier 100 in a manner that forms a layer therebetween. This can be accomplished by applying the liquid adhesive to the carrier 100, to each module 200, or to both. Application of the curable adhesive to each module can involve applying the adhesive to a backside or other mounting surface, as may be applicable. Where the properties of the curable adhesive and the carrier are appropriately tuned, the cured adhesive can then stick to the carrier and not the module upon separation. Furthermore, use of such a liquid curable adhesive can allow for mounting at non-flat surfaces, since the flowing nature of the liquid can readily accommodate any features or non-flat regions on the mounting surface.

FIG. 2C illustrates in front perspective view an exemplary automated adhesive to carrier application according to various embodiments of the present disclosure. Adhesive application 260 can involve the use of an automated adhesive placement tool 262, which can be configured to distribute a liquid UV-curable epoxy or other suitable adhesive 220 onto a carrier 100 in a predefined pattern. The adhesive 220 can be a silicone or other suitable UV-curable material. As shown, the predefined pattern can be in the form of a continuous bead, such as a trace or line about each mounting position for a separate component on the carrier 100. In some embodiments, this pattern can involve forming a trace or line of adhesive around a hole 112 and/or other features in the carrier 100 at each mounting position. The adhesive can be in liquid form, such that it may be spread or otherwise moved about during mounting of each component and prior to a UV-cure phase or other hardening or solidifying step. The liquid form adds flexibility to the mounting process, since it is then possible to use non-planar mounting surfaces on the component(s), the carrier, or both.

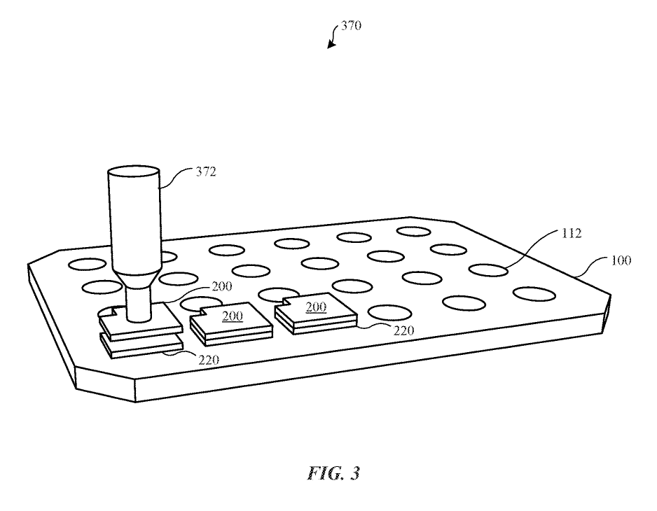

Continuing with FIG. 3, an exemplary automated module placement application to the carrier and adhesive is similarly shown in front perspective view. Module placement application 370 can involve the use of a robotic arm or other robotic component 372 that is configured to place a SIP or module 200 atop a layer of adhesive 220 that is already formed on an upper surface of the carrier 100. Robotic component 372 can be a pick and place robotic machine in some cases. In various embodiments, this can involve the placement of multiple modules 200 atop multiple sections or patterns of adhesive 220, as shown. The combined processes of FIG. 2C and FIG. 3 can involve placing a layer of adhesive 220 and module 200 atop one, some, or all of the different mounting locations, each of which can be designated by a hole 112, for example.

When a module 200 is placed and pressed to the carrier 100 with a trace or line of adhesive 220 located therebetween, the adhesive 220 can be thereby spread outward to some or all of the perimeter edges of the module 200, as shown. Again, the adhesive 220 can be a UV-curable material in a liquid state at the time that the module 200 is placed to the carrier 100. Also, while UV-curable is often recited herein for purposes of illustration, it will be readily appreciated that other types of curable epoxies, resins, or liquids may alternatively be used. The spreading of the liquid adhesive 220 in this manner can facilitate the formation of a continuous seal around the perimeter of the module, such that a mounting surface on the module is sealed away from the undesirable possibility of any sputter or other process material getting underneath the module 200 or between the module 200 and the carrier 100. Again, the mounting surface on the carrier can be warped, curved, and/or have one or more 3D features, and the flowing and spreading nature of the liquid adhesive readily accounts for such non-planarity anywhere on the mounting surface.

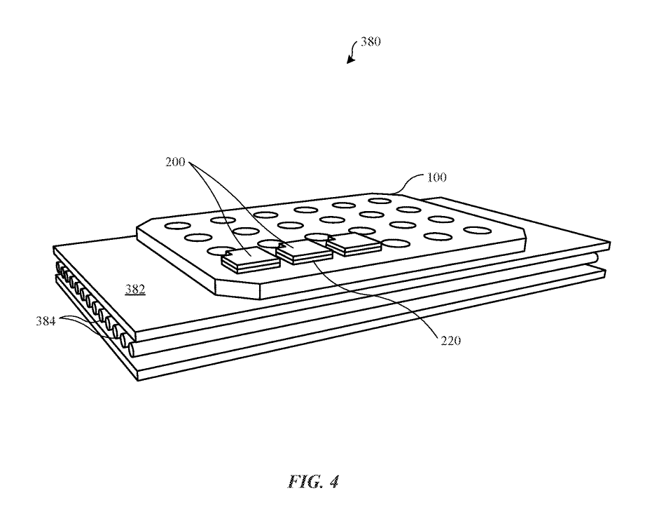

FIG. 4 illustrates in front perspective view an exemplary automated UV-layer curing process according to various embodiments of the present disclosure. UV-layer curing process 380 can include a conveyor 382 or other apparatus configured to move components in proximity to a UV light system 384 having one or more UV lamps or lights, which can be configured to provide sufficient UV light to cure a UV-curable material. Components moved through curing process 380 can include a carrier 100 having one or more modules 200 mounted thereto, with adhesive 220 being located between the carrier 100 and each such module 200. The UV light system 384 can then provide sufficient UV light at a suitable intensity over a suitable time period that the adhesive 220 is thereby cured or otherwise hardened from a liquid to a firm state, such as a solid. A module 200 is thus locked or otherwise coupled to the carrier 100 by way of this UV-layer curing process 380.

In various embodiments, the curing process can transform the epoxy or other UV-curable material from a wet toothpaste or silicone type texture to a dried rubberized type texture. The cured epoxy or other UV-curable material 220 then retains or holds the module 200 or other component to the glass or other carrier 100, and also isolates the mounting surface or adhered region of the module 200 from outside air and processing materials. The cured adhesive layer can adhere to the glass or other carrier 100 stronger than it adheres to the module 200 or other processed component, which facilitates removal at a later time.

With the modules 200 or other components firmly retained or coupled to the carrier 100, the entire unit can then be subjected to a manufacturing process, such as a sputter or plating process. In some embodiments, the holes 112 in the carrier 100 can function to vent at least some portion of the backside of each respective module 200 during the sputter or other process. After the sputter, plating, or other relevant manufacturing process is finished, the sputtered or otherwise processed modules 200 can then be peeled or otherwise removed from the carrier 100. Again, one or more ejection holes 112 can be used to facilitate the removal process, such as by way of a pin or other item being inserted into the hole to push the module 200 away from the carrier 100. Such an ejection process using pins or other items may also be automated, as may be readily appreciated.

Because the UV-cured adhesive layer 220 adheres more strongly and readily to the carrier 100 than to the module 200, removal of the module 200 from the carrier 100 results in the adhesive layer 220 sticking to and remaining with the carrier 100 and not the module 200. In some embodiments, little to no adhesive residue remains with the module 200 at all, such that the module is immediately ready to be mounted to another surface for a further processing step without requiring any cleaning or further surface preparation or processing. The carrier 100 can then be cleaned or otherwise have the adhesive layer 220 removed therefrom, such that it may be reused for a separate new sputter or other manufacturing process with one or more new modules.

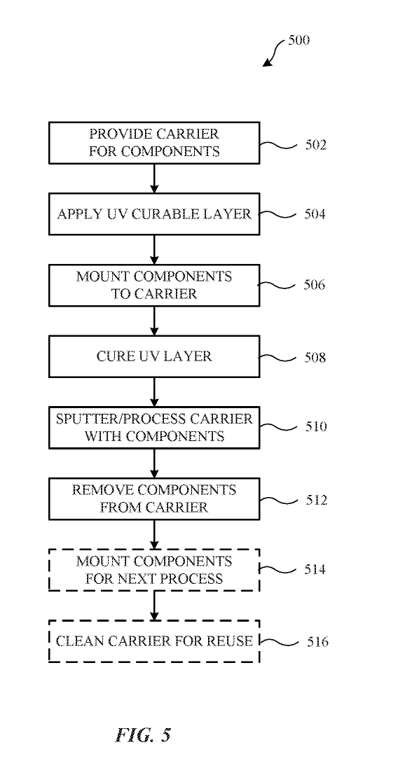

Turning next to FIG. 5, a flowchart of an exemplary method for retaining a module during a sputter process is provided. Again, while a module and a sputter process are recited for purposes of illustration, it will be understood that any component and any manufacturing process requiring the component to be retained may be applicable. Method 500 can be carried out by one or more processors or other controllers that may be associated with a module retention system, such as to control various automated processing components, for example. Method 500 can start at a process step 502, where a carrier for retaining one or more components is provided.

At the next process step 504, a curable layer is applied, which layer can be formed from a UV-curable liquid. Again, this layer can be an adhesive material that is applied to the component(s), to the carrier, or to both. At process step 506, the component(s) can be mounted to the carrier. This mounting step can involve spreading the adhesive to form a layer that is distributed between the component(s) and the carrier. The mounting surface of the component(s) need not be planar, and can be warped, curved, three-dimensional, and/or have one or more protruding or recessed features. Use of a curable liquid provides for such flexibility in use with non-planar mounting surfaces. The curable adhesive layer may also seal off a component mounting surface or portion thereof. At process step 508, the UV-curable layer is then cured, such as by adequate exposure to a UV light source or system. A sputter or other manufacturing process can then be performed at a following process step 510. This sputter process can be performed on the entire carrier, cured adhesive, and component combination, and may form a coating or layer of sputtered material atop the component(s). In various embodiments, the sputtered material is sealed off from and does not contact a mounting surface of the component(s).

At process step 512, the component(s) can be removed from the carrier. Again, this can be facilitated by way of one or more ejection holes in the carrier, which can allow for pins or other items to push the component(s) away from the carrier. As part of the removal process, most or all of the cured adhesive layer can stick to or otherwise remain with the carrier. Accordingly, little to no adhesive contamination stays with the removed component(s). At an optional following process step 514, the component(s) can then be mounted or re-mounted to another surface for a following manufacturing process. This can take place without any cleaning or other surface preparation for the component(s), since no adhesive has remained to contaminate any component surfaces. At another optional process step 516, the carrier can then be cleaned and prepared for future use with one or more new components. This can involve removing the cured adhesive layer from the carrier. As will be readily appreciated, removal of the adhesive layer and adhesive contamination from the carrier can be much easier and cheaper than removal of such adhesive items from the processed component(s), since more care is generally needed for processing the more relatively sensitive component(s).

For the foregoing flowchart, it will be readily appreciated that not every step provided is always necessary, and that further steps not set forth herein may also be included. For example, added steps that involve designing and forming the carrier may be added. Also, steps that provide more detail with respect to applying a liquid adhesive in preformed patterns may also be added. Furthermore, the exact order of steps may be altered as desired, and some steps may be performed simultaneously.

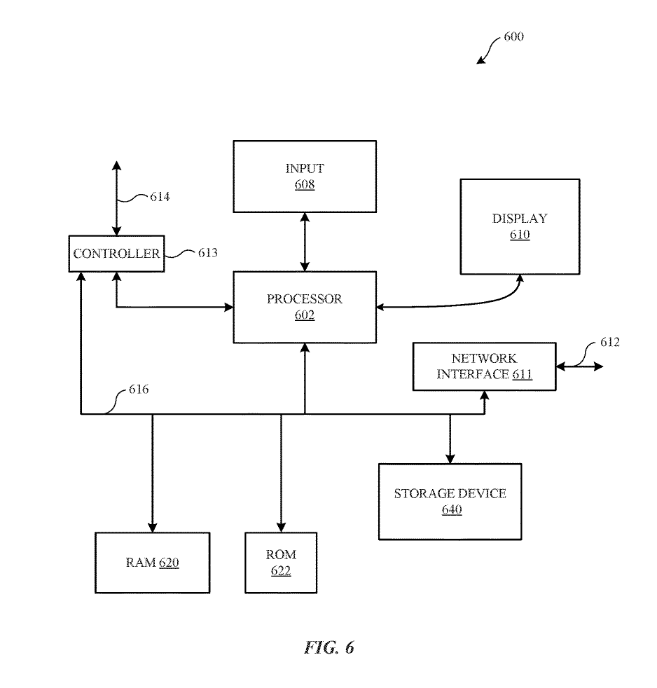

FIG. 6 illustrates in block diagram format an exemplary computing device 600 that can be used to implement the various components and techniques described herein, according to some embodiments. In particular, the detailed view illustrates various components that can be included in an electronic device suitable for operating an automated module retention system, such as that which is shown in FIGS. 1-5. As shown in FIG. 6, the computing device 600 can include a processor 602 that represents a microprocessor or controller for controlling the overall operation of computing device 600. The computing device 600 can also include a user input device 608 that allows a user of the computing device 600 to interact with the computing device 600. For example, the user input device 608 can take a variety of forms, such as a button, keypad, dial, touch screen, audio input interface, visual/image capture input interface, input in the form of other sensor data, etc. Still further, the computing device 600 can include a display 610 (screen display) that can be controlled by the processor 602 to display information to the user (for example, a movie or other AV or media content). A data bus 616 can facilitate data transfer between at least a storage device 640, the processor 602, and a controller 613. The controller 613 can be used to interface with and control different equipment through and equipment control bus 614. The computing device 600 can also include a network/bus interface 611 that couples to a data link 612. In the case of a wireless connection, the network/bus interface 611 can include a wireless transceiver.

The computing device 600 can also include a storage device 640, which can comprise a single disk or a plurality of disks (e.g., hard drives), and includes a storage management module that manages one or more partitions within the storage device 640. In some embodiments, storage device 640 can include flash memory, semiconductor (solid state) memory or the like. The computing device 600 can also include a Random Access Memory (RAM) 620 and a Read-Only Memory (ROM) 622. The ROM 622 can store programs, utilities or processes to be executed in a non-volatile manner. The RAM 620 can provide volatile data storage, and stores instructions related to the operation of the computing device 600.

The various aspects, embodiments, implementations or features of the described embodiments can be used separately or in any combination. Various aspects of the described embodiments can be implemented by software, hardware or a combination of hardware and software. The described embodiments can also be embodied as computer readable code on a computer readable medium. The computer readable medium is any data storage device that can store data which can thereafter be read by a computer system. Examples of the computer readable medium include read-only memory, random-access memory, CD-ROMs, DVDs, magnetic tape, hard disk drives, solid state drives, and optical data storage devices. The computer readable medium can also be distributed over network-coupled computer systems so that the computer readable code is stored and executed in a distributed fashion.

The foregoing description, for purposes of explanation, uses specific nomenclature to provide a thorough understanding of the described embodiments. However, it will be apparent to one skilled in the art that the specific details are not required in order to practice the described embodiments. Thus, the foregoing descriptions of specific embodiments are presented for purposes of illustration and description. They are not intended to be exhaustive or to limit the described embodiments to the precise forms disclosed. It will be apparent to one of ordinary skill in the art that many modifications and variations are possible in view of the above teachings.

What is claimed is:

1. A component retention system configured to hold an electronic component during a manufacturing process, the component retention system comprising:
a carrier configured for mounting the electronic component thereto, the carrier being formed from a material that is transparent; and
an adhesive configured to form a curable adhesive layer between the electronic component and the carrier such that the cured adhesive layer couples the electronic component to the carrier, wherein all of the adhesive layer is removed from the electronic component when the electronic component is removed from the carrier.

2. The component retention system of claim 1, wherein the adhesive is curable when exposed to ultraviolet (“UV”) light and the cured adhesive layer holds the electronic component to the carrier during a sputter process.

3. The component retention system of claim 2, wherein the cured adhesive layer forms a seal that prevents any sputter material from contacting a mounting surface of the electronic component.

4. The component retention system of claim 1, wherein the carrier is further configured for mounting a plurality of separate electronic components thereto.

5. The component retention system of claim 1, wherein the carrier includes an opening therethrough.

6. The component retention system of claim 5, wherein the opening is configured for a pin to be inserted therethrough to push the electronic component away from the carrier.

7. The component retention system of claim 1, wherein the carrier defines a thickness of about 5-20 mm.

8. The component retention system of claim 1, further including:
an automated adhesive placement tool configured to distribute the adhesive onto the carrier in a predefined pattern;
a robotic component configured to place the electronic component on the carrier; and
a UV light system configured to cure the adhesive.

9. A method of retaining a module for a sputter process, the method comprising:
mounting a first surface of the module to a carrier using an adhesive, wherein the adhesive forms an adhesive layer between the first surface and the carrier;
curing the adhesive layer;
sputtering a material on a second surface of the module; and
removing the module from the carrier, wherein all of the adhesive layer is removed from the module when the module is removed from the carrier.

10. The method of claim 9, wherein the adhesive includes a UV-curable material.

11. The method of claim 10, wherein the carrier is formed from a UV-transparent material and curing the adhesive layer includes:
exposing the module, adhesive layer, and carrier to UV light.

12. The method of claim 9, wherein mounting the module includes:
mounting a plurality of separate modules to the carrier.

13. The method of claim 9, wherein removing the module from the carrier includes:
pushing a pin that through an opening in the carrier.

14. A method of manufacturing electronic components, the method comprising:
applying an adhesive to a carrier, the adhesive being a liquid;
placing an electronic component onto the adhesive;
curing the adhesive;
performing a manufacturing process to the electronic component; and
removing the electronic component from the carrier, wherein all of the adhesive is removed from the electronic component thereby.

15. The method of claim 14, wherein performing a manufacturing process includes:
sputtering a material to a first portion of the electronic component.

16. The method of claim 15, wherein curing the adhesive seals a second portion of the electronic component to the carrier and prevents sputter material from contacting the second portion.

17. The method of claim 15, further comprising:
performing a second manufacturing process after removing the electronic component from the carrier, wherein the electronic component is not cleaned prior to performing the second manufacturing process.

18. The method of claim 14, further comprising:
cleaning the adhesive from the carrier.

19. The method of claim 14, wherein the electronic component is a first electronic component, and further comprising:
placing a second electronic component onto the adhesive.

20. The method of claim 19, wherein the manufacturing process is performed to the first electronic component and the second electronic component simultaneously.
